(19) United States
(12) Patent Application Publication
(10) Pub. No.: US 2010/0027610 A1
(43) Pub. Date: Feb. 4, 2010

(54) EQUALIZER AND EQUALIZATION METHOD

(75) Inventor: Chiao-Chih CHANG, Taipei City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/183,261

(22) Filed: Jul. 31, 2008

(51) Int. Cl. H04L 27/01; H03H 7/30

(52) U.S. Cl. 375/233; 708/323

(57) ABSTRACT

An equalizer generates an equalized sample from a plurality of received samples in which a forward equalizer filters a received sample to generate a FE output. A feedback equalizer filters the equalized sample to generate a FBE output. An integrator adds the FE and FBE outputs to generate the equalized sample. The feedback equalizer comprises first and a second sub-filters. The first sub-filter has a first bit-width capability to generate a first FBE output from the equalized sample. The second sub-filter has a second bit-width capability to generate a second FBE output from the equalized sample. The first bit-width is higher than the second bit-width, and the first and second FBE outputs jointly organize the FBE output.

### BACKGROUND OF THE INVENTION

1. Field of the Invention

The invention relates to telecommunication, and in particular, to an enhanced architecture for adaptive equalizers.

2. Description of the Related Art

FIGS. 1a and 1b show conventional equalizer architectures. In FIG. 1a, an equalizer comprises a forward equalizer 110 and a feedback equalizer 140. The forward equalizer 110 receives a received sample r(n) to generate a FE output contributed to a integrator 120. A slicer 130 performs a hard decision to the equalized sample y(n) and generates a decision value d(n). The feedback equalizer 140 filters the decision value d(n) and generates a FBE output to the integrator 120. The integrator 120 adds the FE and FBE outputs to organize the equalized sample y(n). In FIG. 1b, the input to the feedback equalizer 140 is an alternative of the equalized sample y(n) and decision value d(n). A multiplexer 150 is provided, coupled to the integrator 120 and slicer 130 to select the equalized sample y(n) or decision value d(n) as an input to the decision feedback equalizer 140. The alternative mode is referred to as a blind decision.

The forward equalizer 110 and feedback equalizer 140 each are also referred to as a finite impulse response (FIR) filter, and combined as an infinite impulse response (IIR) filter. Conventionally, a FIR filter comprises coefficients (not shown) recursively updated by a least mean square (LMS) algorithm, and a delay line sequentially delaying the input samples. A filter value is generated by multiplying a corresponding coefficient and a delayed sample. In FIGS. 1a and 1b, the forward equalizer 110 and decision feedback equalizer 140 are typically implemented by identical hardware. For example, the forward equalizer 110 and decision feedback equalizer 140 may comprise a plurality of tap cells 102 cascaded in series, performing the FIR filtering operation with the input samples to generate a plurality of filter values correspondingly. The integrator 104 in the forward equalizer 110 or feedback equalizer 140 then sums up the filter values generated from the tap cells 102 to form the FE or FBE output.

The received sample r(n) and equalized sample y(n) are typically digital codes of predetermined bits. For example, the received sample r(n) and equalized sample y(n) may be 16-bit digits. The decision value d(n) generated by the slicer 130 may be only 3 bits. In FIG. 1a, the forward equalizer 110 is implemented to have sufficient bit-width capabilities for handling the 16-bit samples, whereas the decision feedback equalizer 140 is implemented for only the 3-bit decision value d(n), depending on the modulation specification. In FIG. 1b, the forward equalizer 110 and feedback equalizer 140 are both to have 16-bit capabilities due to the blind decision architecture. Each tap cell 102 in the forward equalizer 110 and feedback equalizer 140 comprises multipliers, memory and adders performing the FIR filtering operation, with the hardware thereof implemented according to the bit-width requirement. A higher bit-width requirement exponentially increases layout area consumption, thus a more cost effective way to implement the blind decision architecture is desirable.

### BRIEF SUMMARY OF THE INVENTION

An exemplary embodiment of an equalizer generates an equalized sample from a plurality of received samples in which a forward equalizer filters a received sample to generate a FE output. A feedback equalizer filters the equalized sample to generate a FBE output. An integrator adds the FE and FBE outputs to generate the equalized sample. The feedback equalizer comprises first and a second sub-filters. The first sub-filter has a first bit-width capability to generate a first FBE output from the equalized sample. The second sub-filter has second bit-width capability to generate a second FBE output from the equalized sample. The first bit-width is higher than the second bit-width, and the first and second FBE outputs jointly organize the FBE output.

The feedback equalizer further comprises a mapping device coupled to the output of integrator and input of the second sub-filter, converting the bit-width of the equalized sample to generate a feedback sample of the second bit-width. The second sub-filter filters the feedback sample to generate the second FBE output. The mapping device may be a slicer or a trellis coded modulation (TCM) decoder.

The equalizer further comprises a slicer and a multiplexer. The slicer is coupled to the integrator, slicing the equalized sample to generate a decision value of the second bit-width. The multiplexer is coupled to the integrator and slicer, selecting the equalized sample or the decision value as an input to the first sub-filter; wherein the first sub-filter generates the first FBE output from the selection from multiplexer.

Another embodiment provides an equalization method implemented by the equalizer. A received sample is filtered to generate a FBE output having a first bit-width. The equalized sample is filtered to generate a FBE output. The FE and FBE outputs are added to generate the equalized sample. Generation of FBE output comprises performing a finite impulse response filtering operation to generate a first FBE output from the equalized sample; converting the equalized sample to generate a feedback sample having a second bit-width; and performing a finite impulse response filtering operation to generate a second FBE output from the feedback sample. A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a and 1b show conventional equalizer architectures;

FIG. 2 shows an embodiment of an equalizer according to the invention;

FIG. 3 shows an embodiment of the feedback equalizer 200 according to FIG. 2; and

FIG. 4 is a flowchart of an embodiment of an equalization method.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

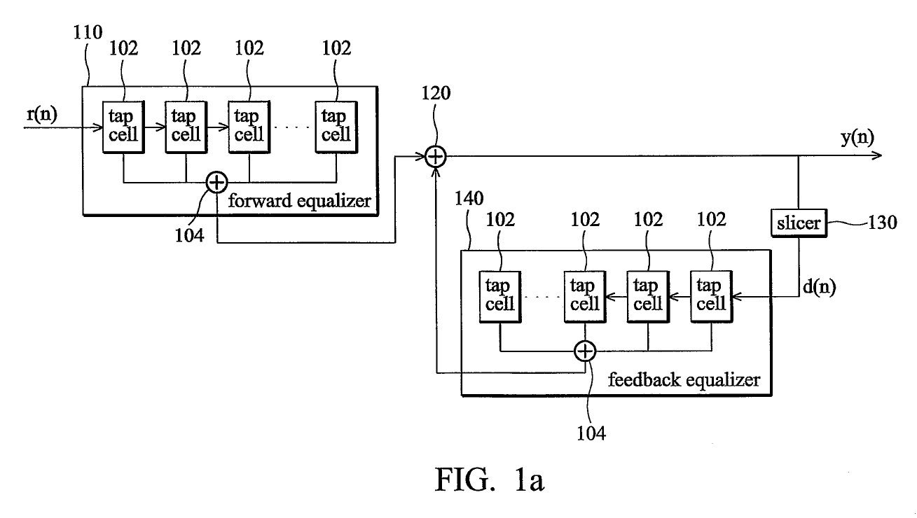

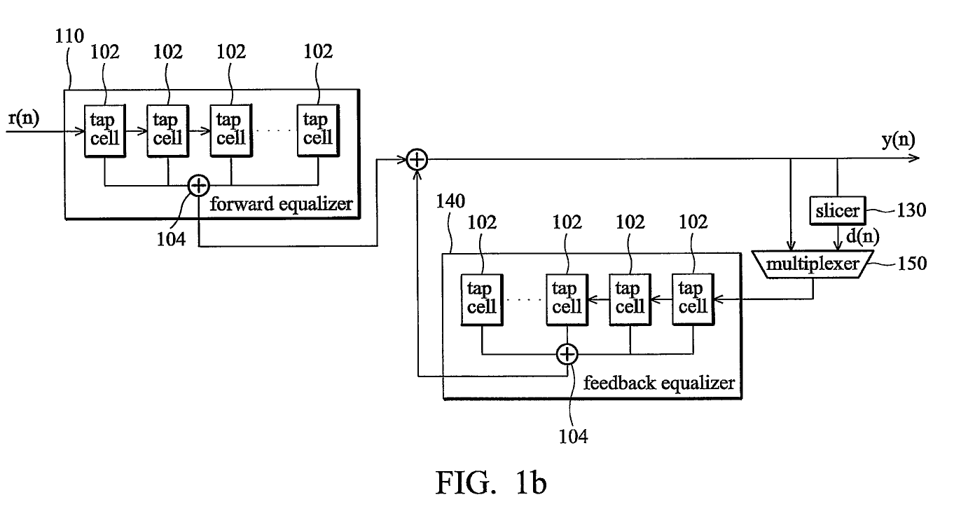

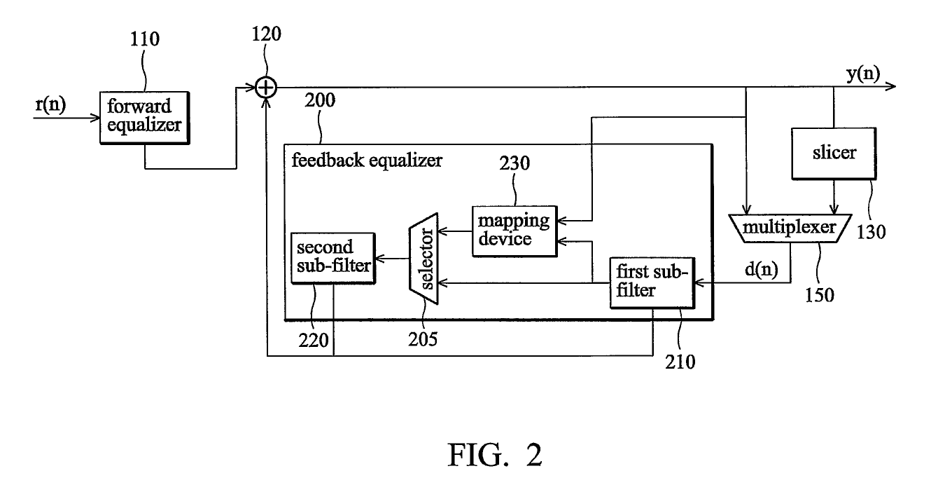

FIG. 2 shows an embodiment of an equalizer according to the invention. A decision feedback equalizer 200 is provided to substitute the decision feedback equalizer 140 in FIG. 1b. The decision feedback equalizer 140 comprises first sub-filter 210 and second sub-filter 220, each having different bit-width capability. For example, the second sub-filter 220 is a compact version capable of processing 3-bit samples, and the first sub-filter 210 is a full version capable of processing 16-bit samples. The number of total tap cells in the decision feedback equalizer 200 may be identical to that in the decision feedback equalizer 140, with ¼ thereof implemented in the first sub-filter 210, and ¾ in the second sub-filter 220. The layout area of the feedback equalizer 200 is greatly reduced since ¾ of the tap cells are compact. The feedback equalizer 200 may also be implemented to substitute the feedback equalizer 140 in FIG. 1a, receiving the equalized sample y(n) and decision value d(n) to generate a FBE output. Detailed operations in the feedback equalizer 200 are described below.

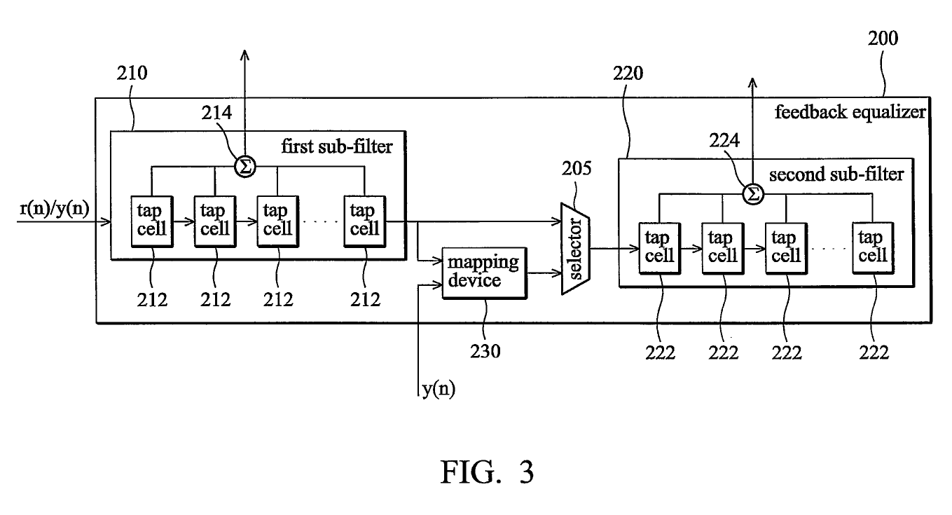

FIG. 3 shows an embodiment of the feedback equalizer 200 according to FIG. 2. The first sub-filter 210 comprises a plurality of first tap cells 212 coupled in series, each storing a coefficient updated recursively based on a least mean square (LMS) algorithm. The number of first tap cells 212 may only be ¼ the number of tap cells 102 in the conventional feedback equalizer 140. Data-width of the first tap cells 212 are 16 bits. The first tap cells 212 sequentially delay the decision value or the equalized sample and generate a plurality of filter values with the coefficients. A first integrator 214 adds the filter values to generate the first DFE output. The input to the first sub-filter 210 is sent from a multiplexer 150, and the equalized sample y(n) or the decision value d(n) is selected thereby. The first sub-filter 210 may be a FIR filter performing a filtering operation to generate the first DFE output, with a delayed sample generated from the equalized sample. The delayed sample is a delay value of the decision value or the equalized sample output from the last first tap cell 212 in the first sub-filter 210. If the delay value is generated from the equalized sample y(n), the bit-width thereof is 16 bit. Likewise, if the delay value is generated from the decision value, the bit-width thereof is 3 bit. For example, if the number of first tap cells 212 is i, the delayed sample output therefrom is denoted as d(n−i) or y(n−i). The first sub-filter 210 is designed to be 16-bit, capable of handling both decision value d(n) and equalized sample y(n) and generating corresponding delayed samples d(n−i) or y(n−i). The second sub-filter 220 is designed to be a 3-bit FIR filter, processing further filtering of the delayed samples d(n−i)/y(n−i) or the equalized sample y(n) to provide compact and cost efficient decision feedback equalization. Since the second sub-filter 220 can only process 3-bit input data, a mapping device 230 is provided to convert the 16-bit delayed sample y(n−i) or equalized sample y(n) to a 3 bit feedback sample. The mapping device 230 may be a slicer or a TCM decoder, performing hard decision to the delayed sample d(n−i)/y(n−i) to generate a feedback sample as an input to the second sub-filter 220.

In FIG. 3, a selector 205 selects the output samples from first sub-filter 210 and mapping device 230 as an input to the second sub-filter 220, and the selection may vary under different conditions. For example, in a direct decision mode, the equalized sample y(n) is converted by the mapping device 230 and sent to the second sub-filter 220 for compact equalization, and a 3-bit DFE output is generated from the second integrator 224. Simultaneously, the first sub-filter 210 filters the decision value d(n) or equalized sample y(n) to generate a 16-bit DFE output from the first integrator 214. The two DFE outputs, with FE output from the forward equalizer 110, are then integrated in the integrator 120 in FIG. 2 to generate the equalized sample. In an alternative mode, the input to second sub-filter 220 is dependent on the input to first sub-filter 210. If the multiplexer 150 in FIG. 2 selects equalized sample y(n) as an input to the first sub-filter 210, the delayed sample y(n−i) is then sent to the mapping device 230 for bit-width conversion, and the selector 205 selects the conversion result therefrom as an input to the second sub-filter 220. Otherwise, if the multiplexer 150 selects decision value d(n) as an input to the first sub-filter 210, the delayed sample d(n−i) is also 3-bit, compatible for the second sub-filter 220. In this case, the selector 205 directly passes the delayed sample d(n−i) to the second sub-filter 220. The FBE outputs generated from the first sub-filter 210 and second sub-filter 220 are thus sent to the integrator 120 for generation of the equalized sample y(n). In a further embodiment, if the feedback equalizer 200 is used to substitute the feedback equalizer 140 in FIG. 1a, the first sub-filter 210 filters the decision value d(n) to generate a first FBE ouput, and the decision value d(n) is delayed to be a d(n−i). The second sub-filter 220 receives the feedback sample converted from the d(n−i) or the equalized sample y(n) via the selector 205, where bit-width of the equalized sample y(n) is converted through the mapping device 230.

In the embodiments, memory storage, delay line, multipliers and adders in a FIR filter may be implemented in conventional fashion to meet the bit-width requirements, thus detailed descriptions are omitted. The structures shown in the first sub-filter 210 and second sub-filter 220 are not intended to limit the disclosure. The bit-widths of the first sub-filter 210 and second sub-filter 220 are not limited to 16 bits and 3 bits. The decision feedback equalizer 200 may also be implemented with more than two sub-filters, each having different bit-width capabilities. The inputs to each sub-filter can be flexibly selected from the slicers, TCM decoders or directly fed-back samples. The adding operation of the DFE outputs of different bits in integrator 120 may be accomplished by aligning the most significant bits (MSBs) thereof. Thus, 12-bit data adding a 3-bit data still renders a 12-bit result.

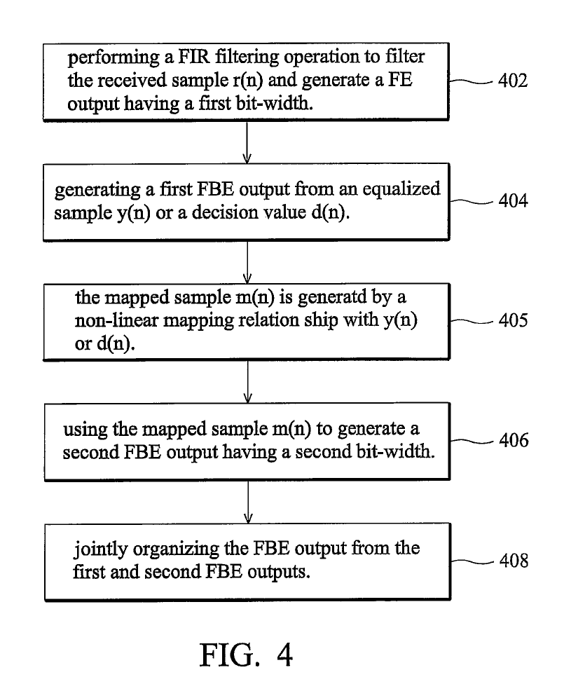

FIG. 4 is a flowchart of an embodiment of the equalization method. In step 402, the forward equalizer 110 performs a FIR filtering operation to filter the received sample r(n) and generate a FE output having a first bit-width. In step 404, the first sub-filter 210 in the feedback equalizer 200 performs a FIR filtering operation to generate a first FBE output from an equalized sample y(n) or a decision value d(n). In step 405, the mapped sample m(n) is generatd by a non-linear mapping relation ship with y(n) or d(n). In step 406, the second sub-filter 220 performs a FIR filtering operation to generate a second FBE output having a second bit-width from the mapped sample m(n). In step 408, the first and second FBE outputs jointly organize the FBE output. The first bit-width is higher than the second bit-width.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An equalizer to generate an equalized sample from a plurality of received samples, comprising:
a forward equalizer, filtering a received sample to generate a forward equalized (FE) output;
a feedback equalizer, filtering the equalized sample to generate a feedback equalized (FBE) output; and
an integrator, adding the FE and FBE outputs to generate the equalized sample; wherein:
the feedback equalizer comprises:
a first sub-filter having a first bit-width capability to generate a first FBE output from the equalized sample; and
a second sub-filter having a second bit-width capability to generate a second FBE output from the equalized sample; wherein:
the first bit-width is higher than the second bit-width; and
the first and second FBE outputs jointly organize the FBE output.

2. The equalizer as claimed in claim 1, wherein:
the feedback equalizer further comprises a mapping device coupled to the output of integrator and input of the second sub-filter, converting the bit-width of the equalized sample to generate a feedback sample of the second bit-width; and
the second sub-filter filters the feedback sample to generate the second FBE output.

3. The equalizer as claimed in claim 2, wherein the mapping device is a slicer or a trellis coded modulation (TCM) decoder.

4. The equalizer as claimed in claim 2, further comprising:
a slicer, coupled to the integrator, slicing the equalized sample to generate a decision value of the second bit-width; and
a multiplexer, coupled to the integrator and slicer, selecting the equalized sample or the decision value as an input to the first sub-filter; wherein the first sub-filter generates the first FBE output from the selection from multiplexer.

5. The equalizer as claimed in claim 4, wherein the first sub-filter comprises:
a plurality of first tap cells coupled in series, each storing a coefficient updated recursively based on a least mean square (LMS) algorithm, and sequentially delaying the decision value or the equalized sample to calculate a plurality of filter values with the coefficients correspondingly;
a first integrator, coupled to the first tap cells, adding the filter values to generate the first FBE output; wherein the first tap cells have the first data-width capabilities.

6. The equalizer as claimed in claim 5, wherein the second sub-filter comprises:
a plurality of second tap cells coupled in series, each storing a coefficient updated recursively based on a least mean square (LMS) algorithm, and sequentially delaying the feedback sample to calculate a plurality of filter values with the coefficients correspondingly; and
a second integrator, coupled to the second tap cells, adding the filter values to generate the second FBE output; wherein the second tap cells have the second data-width capabilities.

7. The equalizer as claimed in claim 6, wherein the number of second tap cells is more than the first tap cells.

8. The equalizer as claimed in claim 1, wherein:
the first sub-filter performs a finite impulse response (FIR) filtering operation to generate the first FBE output and a delayed sample from the equalized sample;
the feedback equalizer further comprises:
a mapping device, coupled to the output of first sub-filter, performing non-linear mapping to the delayed sample to generate a feedback sample of the second bit-width; and
a selector, coupled to the first sub-filter and mapping device, selecting one of the feedback sample and the delayed sample as an input to second sub-filter; and
the second sub-filter filters the selection from selector to generate the second FBE output.

9. The equalizer as claimed in claim 8, wherein the mapping device is a slicer or a TCM decoder.

10. The equalizer as claimed in claim 8, further comprising:
a slicer, coupled to the integrator, slicing the equalized sample to generate a decision value; and
a multiplexer, coupled to the integrator and slicer, selecting one of the equalized sample and the decision value as an input to the first sub-filter; wherein the first sub-filter generates the first FBE output from the selection of multiplexer.

11. The equalizer as claimed in claim 10, wherein:
when the multiplexer selects the decision value as the input to the first sub-filter, the selector selects the delayed sample as the input to the second sub-filter; and
when the multiplexer selects the equalized sample as the input to the first sub-filter, the selector selects the feedback sample as the input to the second sub-filter.

12. The equalizer as claimed in claim 10, wherein the first sub-filter comprises:
a plurality of first tap cells coupled in series, each storing a coefficient updated recursively based on a least mean square (LMS) algorithm, and sequentially delaying the decision value or the equalized sample to calculate a plurality of filter values with the coefficients correspondingly;
a first integrator, coupled to the first tap cells, adding the filter values to generate the first FBE output; wherein:
the delayed sample is a delay value of the decision value or the equalized sample output from a last first tap cell; and
the first tap cells have the first data-width capabilities.

13. The equalizer as claimed in claim 12, wherein the second sub-filter comprises:
a plurality of second tap cells coupled in series, each storing a coefficient updated recursively based on a least mean square (LMS) algorithm, and sequentially delaying the delayed sample or the feedback sample to calculate a plurality of filter values with the coefficients correspondingly; and
a second integrator, coupled to the second tap cells, adding the filter values to generate the second FBE output; wherein the second tap cells have the second data-width capabilities.

14. The equalizer as claimed in claim 13, wherein the number of second tap cells is more than the first tap cells.

15. An equalization method to generate an equalized sample from a plurality of received samples, comprising:
filtering a received sample to generate a FE output having a first bit-width;
filtering the equalized sample to generate a FBE output; and
adding the FE and FBE outputs to generate the equalized sample; wherein the generation of FBE output comprises:
performing a finite impulse response filtering operation to generate a first FBE output from the equalized sample; and
converting the equalized sample to generate a mapped sample having a second bit-width; and
performing a finite impulse response filtering operation to generate a second FBE output from the mapped sample; wherein:
the first bit-width is higher than the second bit-width; and
the first and second FBE outputs jointly organize the FBE output.

16. The equalization method as claimed in claim 15, further comprising:
slicing the equalized sample to generate a decision value of the second bit-width; and
generating the first FBE output from the equalized sample or the decision value.

17. An equalization method to generate an equalized sample from a plurality of received samples, comprising:
filtering a received sample to generate a FE output having a first bit-width;
filtering the equalized sample to generate a FBE output; and
adding the FE and FBE outputs to generate the equalized sample; wherein the
generation of FBE output comprises:
performing a finite impulse response filtering operation to generate a first FBE output and a delayed sample from the equalized sample;
performing non-linear mapping to the delayed sample to generate a feedback sample having a second bit-width; and
performing a finite impulse response filtering operation to generate a second FBE output from the mapped sample; wherein:
the first bit-width is higher than the second bit-width; and
the first and second FBE outputs jointly organize the FBE output.

18. The equalization method as claimed in claim 17, further comprising:
slicing the equalized sample to generate a decision value of the second bit-width; and
generating the first FBE output from the equalized sample or the decision value.
